(19) United States
(12) Patent Application Publication
(10) Pub. No.: US 2003/0093740 A1
(43) Pub. Date: May 15, 2003

(54) Iterative hard decoding method for multidimensional SPC

(76) Inventor: Nebojsa Stojanovic, Muenchen (DE)

Correspondence Address: BELL, BOYD & LLOYD, LLC, P. O. BOX 1135, CHICAGO, IL, 60690-1135, US

(21) Appl. No.: 10/274,652

(22) Filed: Oct. 21, 2002

(30) Foreign Application Priority Data
Oct. 19, 2001 (DE) 101 51 747.5

(51) Int. Cl. H03M 13/00

(52) U.S. Cl. 714/752

(57) ABSTRACT

An error correction method is provided for digital data which are transmitted in a data transmission system, particularly an optical transmission system, wherein the bit error rate can be distinctly lowered fairly simply. The error correction method includes generating a multidimensional SPC product code word consisting of a multiplicity of 1-D code words, transmitting the multidimensional SPC product code word to a receiver, performing a hard decoding method with a number of iteration steps, the decoding method including determining the 1-D code words with an odd number of errors, generating an error matrix with the aid of this information, and correcting entries of the multidimensional SPC product code word via a predetermined correction algorithm.

### BACKGROUND OF THE INVENTION

In a data transmission system, data which were originally injected into a transmission line in the form of rectangular pulses (digital) are distorted by various influences. At the receiver end, this can lead to faulty data recovery; that is to say, to bit errors.

To minimize such bit errors, it is known to code the data before they are transmitted. During this process, additional bits (check bits) are generated via the information data, which bits are transmitted together with the information data. Depending on the type of code, indications of the existence of one or more errors and of the position of the error or errors can be derived from the additional information.

After they have been transmitted, the data are finally decoded at the receiver end. For this purpose, a number of decoding methods are known, an essential distinction being made between hard decoding methods and so-called soft decoding methods.

In hard decoding methods, a bit of a received code word is directly converted into a digital value (e.g., +1 or−1) on the basis of decision thresholds. A code word received at the receiver end

C₁=(−0.9−0.2 0.4)

is then converted; for example, into a digital code word

C₁=(−1−1 1).

The soft decoding method is distinguished by the fact that a decision (e.g.,+1 or1) is only made after a number of iteration steps. Until then, analog values are used for the calculation which are modified with each iteration step in accordance with the decoding algorithm used. However, soft decoding methods need relatively complex decoders and are much more complicated and computing-intensive than hard decoding methods.

Hard decoding methods, in contrast, have the disadvantage that the reduction in the bit error rate, that is to say the coding gain, obtained by the coding is relatively small.

It is an object of the present invention, therefore, to provide an error correction method for digital data by using a hard decoding method which provides for a particularly high coding gain.

### SUMMARY OF THE INVENTION

The error correction method of the present invention includes a number of measures which, together, lead to a great improvement in the bit error rate (BER). Firstly, it is proposed to code the data to be transmitted via a multidimensional (particularly, two-dimensional or three-dimensional) SPC (Single Parity Check) product code and to transmit the SPC product code word generated via a transmission line. The SPC product code word is decoded at the receiver end via a hard decoding method, the hard decoding method firstly including the determination of 1-D code words of the SPC product code word with an odd number of errors. According to the present invention, an error matrix is generated from the result of the determination. Finally, the received SPC product code word is corrected via a predetermined correction algorithm on the basis of this error matrix.

To provide a better understanding, the essential terms of the invention will be explained briefly in the text which follows.

A product code is a multidimensional block code with the parameters (n, k, d); n being the code word length, k being the number of information bits and d being the minimum hamming distance. Depending on the type of code, it includes a different number of check bits (n−k). An example of a two-dimensional product code is shown in FIG. 1.

SPC (Single Parity Check) product codes are multidimensional block codes, 1-D subcode words of which only have a single parity bit (nᵢ−kᵢ=1).

A so-called error matrix is a matrix in the cells of which the number of 1-D code words including a cell considered which exhibit an odd number of errors is entered.

According to a preferred embodiment of the present invention, the information data are coded as a 3-D SPC product code word and, in particular, as a concatenated 3-D SPC product code word.

According to a preferred embodiment of the correction algorithm, a bit of the SPC product code word is corrected when the associated cell of the error matrix exhibits a predetermined value. In the case of a 3-D SPC product code word, this value is preferably three. In the case of a 2-D SPC product code word, it is two. If necessary, the predetermined value can be changed to another value, such as two or one, after a number of iteration steps.

The correction algorithm is preferably iteratively repeated a number of times. According to a preferred embodiment of the present invention, the correction algorithm can be changed during the iteration.

As already mentioned, according to a first correction algorithm, a bit of the SPC product code word is corrected when the associated cell of the error matrix has a predetermined value. According to another correction algorithm, a bit of the SPC product code word is only corrected when the associated cell of the error matrix has a predetermined value and the number of entries with this value in the 1-D code words containing the cell has a second predetermined value.

According to another preferred embodiment of the present invention, a concatenated 3-D SPC product code word is generated from the information data. For this purpose, a concatenated SPC coder is used which preferably has two coders and one interleaver. The concatenated 3-D SPC code word has the parameters (k+2,k)³ in this case.

The length of the code word is preferably within a range of between n=8 and n=25 and, particularly, within a range of between n=10 and n=20. The code word length is preferably equally large in each dimension.

Before a hard decoding method is applied, a soft decoding method can be performed.

Additional features and advantages of the present invention are described in, and will be apparent from, the following Detailed Description of the Invention and the Figures.

### BRIEF DESCRIPTION OF THE FIGURES

FIG. 1 shows an example of a two-dimensional product code word.

FIG. 2 shows an example of a three-dimensional SPC product code word.

FIG. 3 shows a diagrammatic representation for explaining the generation of an error matrix.

FIG. 4 shows an example of an error matrix.

FIG. 5 shows a concatenated coder according to an exemplary embodiment of the present invention.

### DETAILED DESCRIPTION OF THE INVENTION

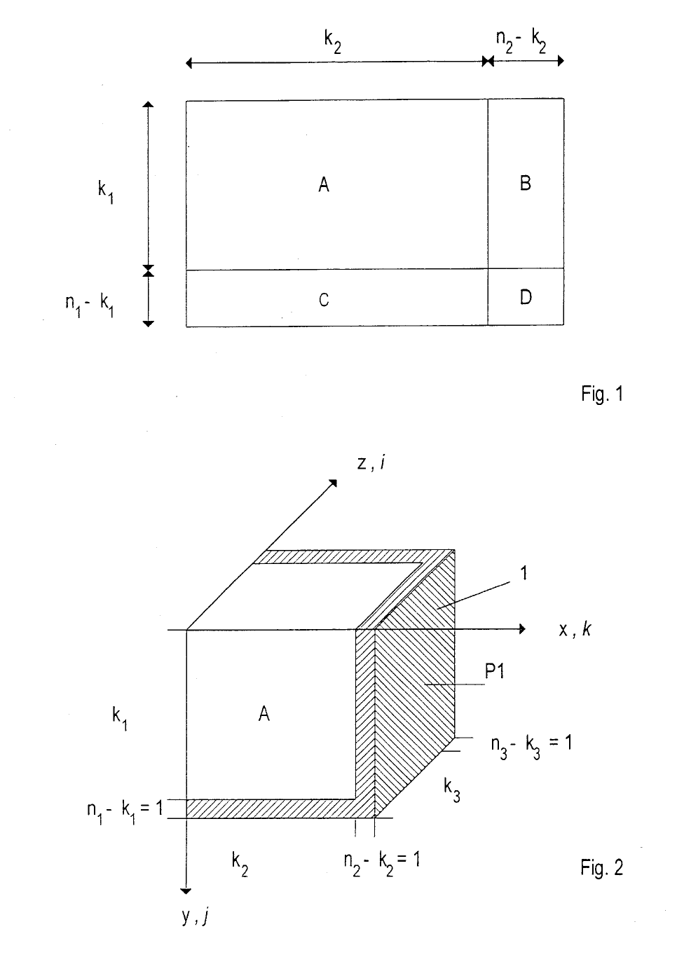

FIG. 1 shows an example of a two-dimensional product code with the parameters (n₁, k₁, d₁)×(n₂, k₂, d₂), n being the code word length, k being the number of information bits and d being the minimum hamming distance. Field A contains the information bits, field B contains the check bits for, in each case, one row of information bits and field C contains the check bits for, in each case, one column of information bits. Each row and column, respectively, of the 2-D product code word forms a 1-D code word.

Incidentally, the 2-D product code word shown is a so-called full product code since separate check bits (field D) are also provided for the check bits (fields C, B).

FIG. 2 shows an example of a three-dimensional SPC product code word 1. The 3-D code word 1 includes a block A with information bits which contains a total of k₁×k₂×k₃ bits. Each row (in the x or z direction) and column (in the y direction) represents a 1-D code word 2 which has a single parity bit in its last position. The parity bits overall are designated by P1.

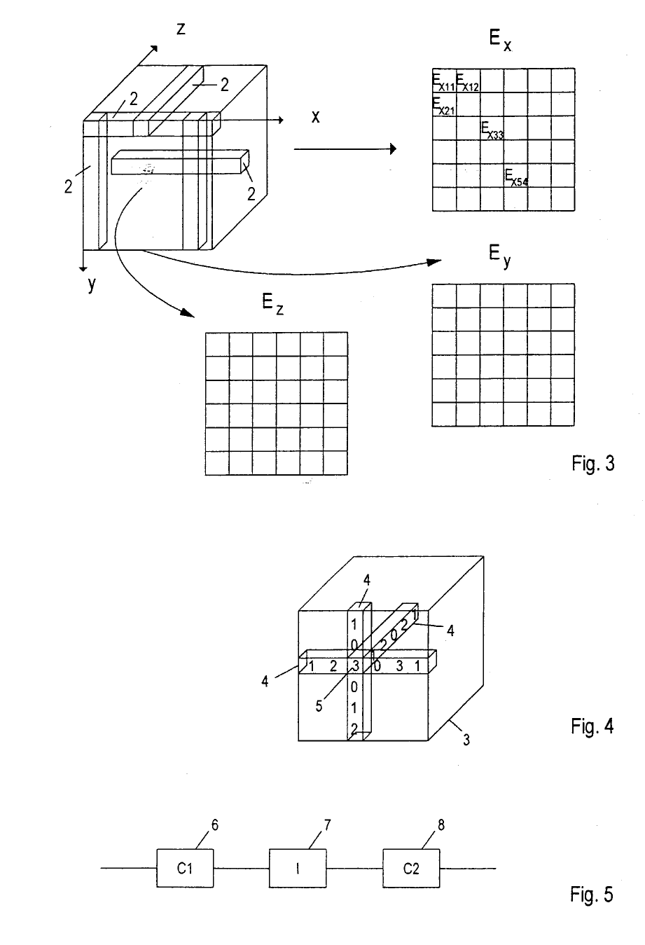

FIG. 3 shows at the top left a view of the 3-D SPC product code word 1 of FIG. 2 in which a number of 1-D code words 2 can be seen. To obtain a three-dimensional error matrix as shown in FIG. 4 from the 3-D SPC product code word 1, 2-D error matrices Ex, Ey and Ez, respectively, are first generated from the 3-D SPC product code word 1 in a first step. The entries Ex_{i, j}, Ey_{i, k} and Ez_{j, k}, respectively, indicate whether the associated 1-D code word 2 contains an odd number of errors. If a code word 2 contains an even number of errors or no error, the value “0”, for example, is assigned to the associated field of the error matrix Ex, Ey and Ez, respectively. If, on the other hand, the 1-D code word 2 contains an odd number of errors, a “1” is assigned, for example, to the associated field of the error matrix.

Finally, the 3-D error matrix shown in FIG. 4 is obtained by adding the entries Ex_{i, j}, Ey_{i, j}, Ez_{j, k} for, in each case, one element E_{i, j, k} of the error matrix 3. A cell 5 of the error matrix 3, having the coordinates i, j, k, for example, receives the value three if each of the 1-D code words 2 (in the x, y and z direction), which contain the cell 5 considered with the coordinates i, j, k, contains an odd number of errors. If only two of the three 1-D code words 2 which include the cell 5 with the coordinates i, j, k have an odd number of errors, the associated field 5 of the error matrix 3 receives the entry “2”, etc.

Mathematically, the three 2-D error matrices Ex, Ey, Ez can be represented as follows:

E_{X}=[E_{Xi,j}]ₙₓₙ

E_{Y}=[E_{Yi,k}]ₙₓₙ

E_{Z}=[E_{Zj,k}]ₙₓₙ (1)

where n is the code word length.

The entries Ex_{i, j}, Ey_{i, k}, Ez_{j, k}, which specify whether the corresponding 1-D code word contains an odd number of errors, are calculated as follows:

$$\begin{matrix}{E}_{X i , j} = ( {\sum }_{k = 1}^{n} {a}_{i , j , k} ) mod 2 \\ {E}_{Y i , k} = ( {\sum }_{j = 1}^{n} {a}_{i , j , k} ) mod 2 \\ {E}_{Z j , k} = ( {\sum }_{i = 1}^{n} {a}_{i , j , k} ) mod 2\end{matrix} \qquad ( 2 )$$

Finally, the entries of the 3-D error matrix 3 are obtained from the following relation:

E_{i,j,k}=E_{Xi,j}+E_{Yi,k}+E_{Zj,k} (3)

To correct errors contained in the received 3-D SPC code word, a multiplicity of correction algorithms now can be used which also can be alternated during the iteration.

A first variant of the correction algorithm consists in changing an entry in the 3-D SPC product code word 1 whenever the value E_{i, j, k} in the associated field of the error matrix 3 is equal to “3”. As such, all fields of the 3-D SPC product code 1, the associated fields of the error matrix 3 of which have the value “3”, are changed. As a result, however, errors can be generated in other 1-D code words 2 which lead to new entries

E_{i, j, k}=3 in the error matrix 3. These newly generated values E_{i, j, k}=3 are eliminated in a next iteration step.

Another correction algorithm consists in changing a field of the 3-D SPC code word 1 when the associated entry E_{i, j, k}=3 and, at the same time, the number of entries having the value “3” in the rows and columns 4 of the error matrix 3, which include the cell considered with the coordinates i, j, k, has a predetermined value; e.g., “3”. This can be expressed mathematically by the following relation:

E_{i, j, k}=3 and E³x_{i, j}+E³y_{i, k}+E³z_{j, k}=3, with

$$\begin{matrix}{E}_{X i , j}^{0} = {\sum }_{{k = 1}_{{E}_{i , j , k} = 0}}^{n} ( {E}_{i , j , k} + 1 ) & {E}_{Y i , k}^{0} = {\sum }_{{j = 1}_{{E}_{i , j , k} = 0}}^{n} ( {E}_{i , j , k} + 1 ) & {E}_{Z j , k}^{0} = {\sum }_{{i = 1}_{{E}_{i , j , k} = 0}}^{n} ( {E}_{i , j , k} + 1 ) \\ {E}_{X i , j}^{1} = {\sum }_{{k = 1}_{{E}_{i , j , k} = 1}}^{n} {E}_{i , j , k} & {E}_{Y i , k}^{1} = {\sum }_{{j = 1}_{{E}_{i , j , k} = 1}}^{n} {E}_{i , j , k} & {E}_{Z j , k}^{1} = {\sum }_{{i = 1}_{{E}_{i , j , k} = 1}}^{n} {E}_{i , j , k} \\ {E}_{X i , j}^{2} = {\sum }_{{k = 1}_{{E}_{i , j , k} = 2}}^{n} ( {E}_{i , j , k} - 1 ) & {E}_{Y i , k}^{2} = {\sum }_{{j = 1}_{{E}_{i , j , k} = 2}}^{n} ( {E}_{i , j , k} - 1 ) & {E}_{Z j , k}^{2} = {\sum }_{{i = 1}_{{E}_{i , j , k} = 2}}^{n} ( {E}_{i , j , k} - 1 ) \\ {E}_{X i , j}^{3} = {\sum }_{{k = 1}_{{E}_{i , j , k} = 3}}^{n} ( {E}_{i , j , k} - 2 ) & {E}_{Y i , k}^{3} = {\sum }_{{j = 1}_{{E}_{i , j , k} = 3}}^{n} ( {E}_{i , j , k} - 2 ) & {E}_{Z j , k}^{3} = {\sum }_{{i = 1}_{{E}_{i , j , k} = 3}}^{n} ( {E}_{i , j , k} - 2 )\end{matrix}$$

where E⁰x_{i, j} designates the number of zeros in a row 4 in the x direction of the error matrix 3, E¹x_{i, j} designates the number of ones, etc.

After a number of n iteration steps, the correction algorithm can be changed and, for example, all positions of the 3-D SPC code word, the associated entry of which in the error matrix 3 is E_{i, j, k}=2, can be changed.

The example described above relates to 3-D code words. The same considerations also can be applied to 2-D code words.

It has been found that an optimum bit error rate can be achieved if the code word length is between ten and twenty bits. As a rule, the optimum number of iteration steps is between two and five.

Particularly good results have been obtained when a 3-D SPC product code word is generated from the information data via a serially concatenated coder.

A serially concatenated coder with two coders 6, 8 is shown in FIG. 5. The serially concatenated coder includes a first coder 6 and a second coder 8. The first coder 6 generates a 3-D SPC product code, as shown, for example., in FIG. 2, with a code rate of, for example, (26/27)³.

The 3-D SPC code word 1 output at the output of the first coder 6 is supplied to an interleaver 7 which rearranges the individual bits of the 3-D SPC code word 1.

The 3-D SPC code word output by the interleaver 7 is finally coded by the second coder 8 which generates a three-dimensional SPC product code word with, in each case, one parity bit for each 1-D code word 2. The code rate of the complete concatenated coder is thus (k/k+2)³; in the present example, (26/28)³=0.8. The redundancy of the SPC product code word generated is preferably<25%.

The hard decoding method described above also can be applied in a system in which an iterative soft decoding method is already carried out. The soft decoding method utilizes, for example, a MAX log MAP decoding algorithm.

After a soft decoding method has been carried out, for example, a hard correction algorithm with preferably one or two and possibly even more iterations is performed. During this process, different correction algorithms can be applied.

Although the present invention has been described with reference to specific embodiments, those of skill in the art will recognize that changes may be made thereto without departing from the spirit and scope of the present invention as set forth in the hereafter appended claims.

1. An error correction method for digital data which are transmitted in an optical transmission system, the method comprising the steps of:
generating a multidimensional SPC product code word which consists of a plurality of 1-D code words;
transmitting the SPC product code word to a receiver; and
performing a hard decoding method which includes the steps of determining the 1-D code words with an odd number of errors, generating an error matrix, and correcting errors in the received SPC product code word via a predetermined correction algorithm.

2. An error correction method as claimed in claim 1, wherein the correction algorithm is carried out in a plurality of iterative steps.

3. An error correction method as claimed in claim 1, wherein, to generate the error matrix, the 1-D code words with an odd number of errors, containing a cell, are counted for each cell of the error matrix.

4. An error correction method as claimed in claim 1, wherein the SPC product code word is a 3-D SPC product code word.

5. An error correction method as claimed in claim 1, wherein the predetermined correction algorithm corrects an entry of the received SPC product code word when an associated element of the error matrix has a predetermined value.

6. An error correction method as claimed in claim 5, wherein the predetermined value is two.

7. An error correction method as claimed in claim 5, wherein the predetermined value is three.

8. An error correction method as claimed in claim 1, wherein the predetermined correction algorithm includes the steps of counting entries with a predetermined value in each row and column of the error matrix which contain one cell of the error matrix, and correcting an associated bit of the SPC product code word when a number of entries reaches a predetermined value.

9. An error correction method as claimed in claim 1, wherein different correction algorithms are applied during the iteration.

10. An error correction method as claimed in claim 1, wherein the SPC product code word is generated via a concatenated SPC coder with at least two coders and one interleaver.

11. An error correction method as claimed in claim 1, wherein a length of a 1-D code word is between eight and twenty-five.

12. An error correction method as claimed in claim 1, wherein a length of a 1-D code word is between ten and twenty.

13. An error correction method as claimed in claim 1, the method further comprising the step of performing a soft decoding method on the received SPC product code word before performing the hard decoding method.

14. An error correction method as claimed in claim 13, wherein a decoder utilizes extrinsic information for performing the soft decoding method.

15. An error correction method as claimed in claim 14, wherein the decoder utilizes a max log MAP decoding algorithm for performing the soft decoding method.
